(19) United States
(12) Patent Application Publication
(10) Pub. No.: US 2009/0061635 A1
(43) Pub. Date: Mar. 5, 2009

(54) METHOD FOR FORMING MICRO-PATTERNS

(75) Inventors: Hsiao-Che WU, Chung-Li City (TW); Ming-Yen Li, Fongshan City (TW); Wen-Li Tsai, Renwu Township (TW)

Correspondence Address: Muncy, Geissler, Olds & Lowe, PLLC, P.O. BOX 1364, FAIRFAX, VA, 22038-1364, US

(73) Assignee: ProMOS Technologies Inc.

(21) Appl. No.: 12/108,285

(22) Filed: Apr. 23, 2008

(30) Foreign Application Priority Data
Aug. 29, 2007 (TW) 96132100

(51) Int. Cl. H01L 21/311

(52) U.S. Cl. 438/701; 257/E21.257; 257/E21.258

(57) ABSTRACT

A method for forming micro-patterns is disclosed. The method forms a sacrificial layer and a mask layer. A plurality of first taper trenches is formed in the sacrificial layer. A photoresist layer is filled in the plurality of first taper trenches. The photoresist layer is used as a mask and a plurality of second taper trenches is formed in the sacrificial layer. Then, the photoresist layer is stripped to be capable of patterning a layer by the first taper trenches and the second taper trenches in the sacrificial layer. Therefore, a patterned sacrificial layer duplicating the line density by double etching is formed.

### RELATED APPLICATIONS

This application claims priority to Taiwan Application Serial Number 96132100, filed Aug. 29, 2007, which is herein incorporated by reference.

### BACKGROUND

1. Field of Invention

The present invention relates to semiconductor manufacturing technology. More particularly, the present invention relates to a method for forming micro-patterns on a semiconductor device

2. Description of Related Art

In general, the smallest feature size that photo-lithography technique can define is limited by the wave-length and the coherence of the light source. Before the next generation patterning equipment being developed and commercialized, integrated circuit (IC) manufacturers have tried to break the limit by playing with processing tricks for making finer structures. These techniques could be classified into two groups: double-exposure or spacer patterning technology.

### SUMMARY

An object of the present invention is to provide a method for forming micro-patterns smaller than the feature size that photo-lithography processes can define by double-etching the masking material so as to duplicate the line density.

In accordance with the foregoing and other objectives, the present invention provides a method for forming micro-patterns, comprising forming a sacrificial layer and a masking layer on a substrate, and then double etching of the sacrificial layer dedicated to shortening the line width so as to get the smallest feature size.

In a preferred embodiment of the present invention, the method for forming micro-patterns comprises:

forming a sacrificial layer and a masking layer on a substrate, and then forming a patterned masking layer and a patterned photoresist layer on the sacrificial layer;

using the patterned masking layer and the patterned photoresist layer as a mask to etch the sacrificial layer so as to form a first taper trench;

filling a photoresist layer in the first taper trench, and then using the photoresist layer as a mask to etch the sacrificial layer so as to form a second taper trench; and

stripping the photoresist layer, and etching the masking layer via the first taper trench and the second taper trench so as to form a patterned masking layer.

As embodied and broadly described herein, the invention provides a method for forming micro-patterns which has the following advantages:

Original equipment for manufacturing processes do not need to be changed, and processing tricks to duplicate the line density increases the integration of components on the wafer

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a sectional view showing the formation of a stack layer on a substrate in accordance with the present invention;

FIG. 2 is a sectional view showing the formation of a patterned second masking layer in FIG. 1;

FIG. 3 is a sectional view showing the etching of a sacrificial layer in FIG. 1;

FIG. 4 is a sectional view showing the filling of a photoresist in the first taper trenches in FIG. 3;

FIG. 5 is a sectional view showing the stripping of the patterned second masking layer in FIG. 4;

FIG. 6 is a sectional view showing the etching patterned sacrificial layer in FIG. 5;

FIG. 7 is a sectional view showing the etching of a first masking layer in FIG. 6; and

FIG. 8 is a flowchart according to one preferred embodiment of this invention.

### DESCRIPTION OF THE PREFERRED EMBODIMENTS

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples.

This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

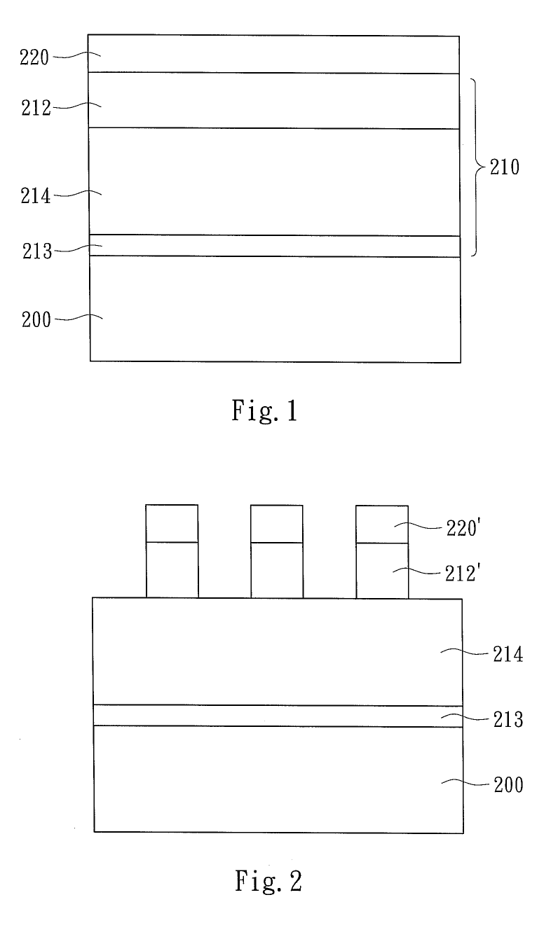

FIG. 1 to FIG. 7 are sectional views illustrating an exemplary manufacturing method for forming micro-patterns on a semiconductor device in accordance with the present embodiment.

Referring to FIG. 1, a substrate 200 is made of a usual material used in semiconductor manufacturing technology. The material of the substrate 200 could be silicon and any other kind of conductor or dielectric materials, but it is not restricted to these materials.

A stack layer 210 is formed on the substrate 200. The stack layer 210 comprises a first masking layer 213, a second masking layer 212 and a sacrificial layer 214. The sacrificial layer 214 and the first masking layer 213 have an etch selectivity ratio and are respectively selected from two of polysilicon, silicon oxide, silicon nitride or nitride. The sacrificial layer 214 and the second masking layer 212 have an etch selectivity ratio and are respectively selected from two of polysilicon, silicon oxide, silicon nitride or nitride. In the present embodiment, the sequence of forming the stack layer 210 is described as followed. The first masking layer 213 is formed on the substrate 200, preferably by deposition. The sacrificial layer 214 is formed on the first masking layer 213, preferably by deposition. The second masking layer 212 is formed on the sacrificial layer 214, preferably by deposition.

In the present embodiment, the first masking layer 213 and the second masking layer 212 are respectively a nitride layer, preferably silicon nitride (SiN). The sacrificial layer 214 is an oxide layer, preferably silicon dioxide (SiO₂).

A photoresist layer 220 is formed on the stack layer 210, preferably with spin coating. The photoresist layer 220 is made of a usual material, such as positive photoresist or negative photresist.

Referring to FIG. 2, a photo-lithography process is performed. A pattern on a mask (e.g., a reticle or photomask) is transferred to the photoresist layer 220 and the second masking layer 212 so as to form a patterned photoresist layer 220′ and a patterned second masking layer 212′. The patterned second masking layer 212′ is used to be a hard mask in the follow-up manufacturing process. In the present embodiment, the way of etching the second masking layer 212 is by dry etching.

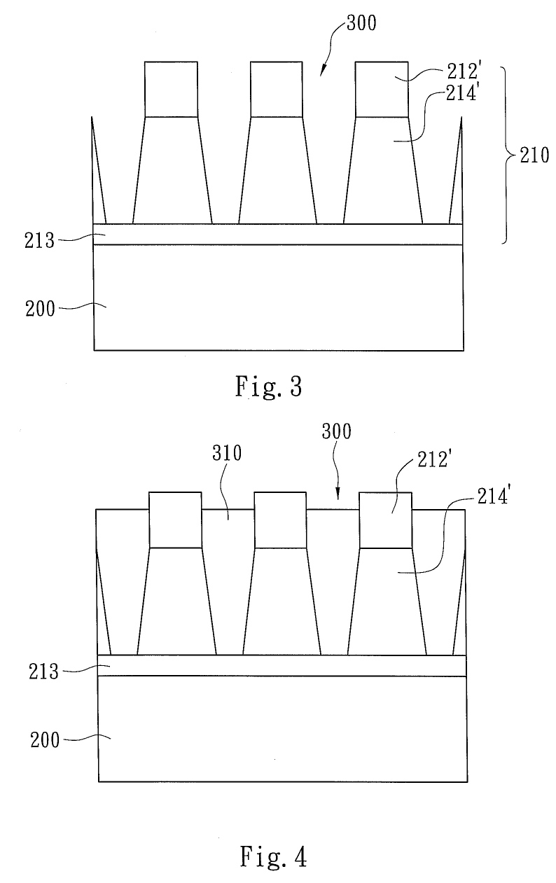

Referring to FIG. 3, the sacrificial layer 214 is etched by using the patterned second masking layer 212′ to be a hard mask so as to form a first patterned sacrificial layer 214′. Then the patterned photoresist layer 220′ is removed. Therefore, one or more first taper trenches 300 are formed in the first patterned sacrificial layer 214′. In the present embodiment, the way of etching the sacrificial layer 214 is by dry etching.

Referring to FIG. 4, in the present embodiment, the photoresist 310 fills in the first taper trenches 300 with spin coating, and then the etching back process is performed to make the photoresist 310 filling the first taper trenches 300 to be lower than the patterned second masking layer 212′.

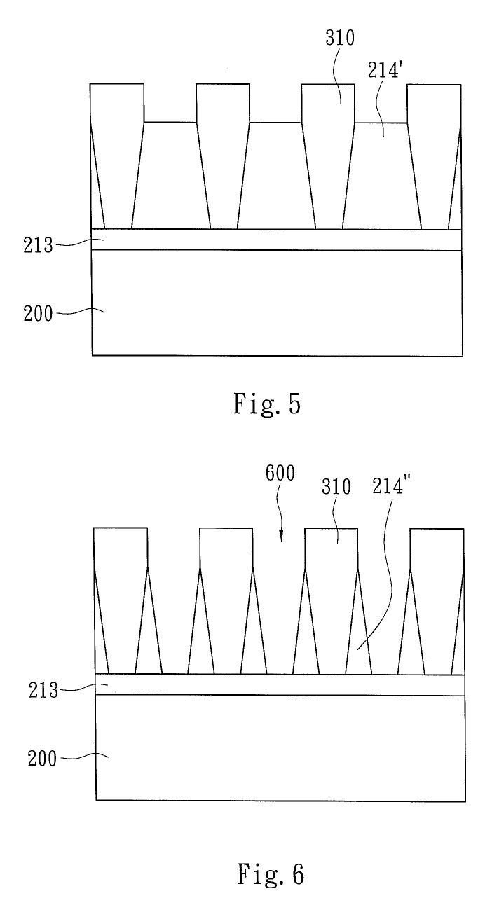

Referring to FIG. 5, the patterned second masking layer 212′ is stripped to expose the top of the first patterned sacrificial layer 214′.

Referring to FIG. 6, the exposed parts of the first patterned sacrificial layer 214′ are etched with the photoresist 310 to be a mask so as to form one or more second taper trenches 600 in the first patterned sacrificial layer 214′. Therefore, the first patterned sacrificial layer 214′ becomes a second patterned sacrificial layer 214″. In the present embodiment, the way of etching the first patterned sacrificial layer 214′ is by dry etching.

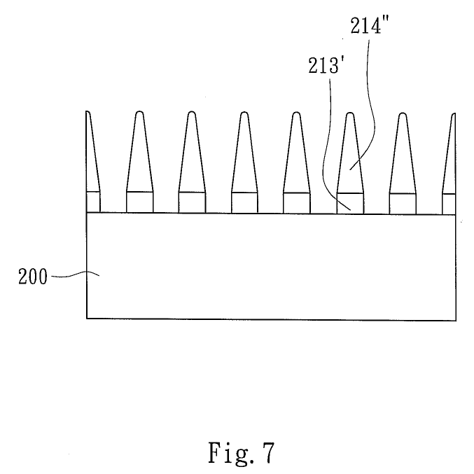

Referring to FIG. 7, the photoresist 310 is stripped, and then the second patterned sacrificial layer 214″ is used as a mask and by etching the first masking layer 213 to form a patterned first masking layer 213′. In another embodiment, the second patterned sacrificial layer 214″ could also be as a mask to etch another layer, such as a substrate, a metal layer or a dielectric layer, etc. In the present embodiment, the way of etching the first masking layer 213 is by dry etching.

Compare FIG. 7 with FIG. 4 in the present embodiment, the line width of the patterned first masking layer 213′ is smaller than the line width of the patterned second masking layer 212′. The line width of the patterned first masking layer 213′ is almost a half of the patterned second masking layer 212′.

In the follow-up manufacturing process, the patterned first masking layer 213′ is used as a mask after the second patterned sacrificial layer 214″ is stripped so as to perform the later manufacturing process.

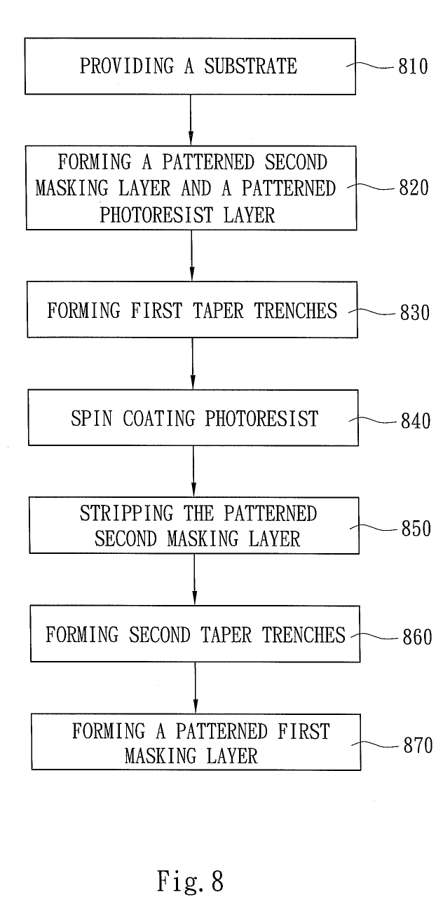

Referring to FIG. 8, which is a flowchart of a method for forming micro-patterns in accordance the present invention. The method comprises procedures as followed.

In Step 810 a substrate is provided. The provided substrate comprises forming a stack layer on the substrate. The stack layer is formed by depositing a first masking layer on the substrate, forming a sacrificial layer on the first masking layer, and depositing a second masking layer on the sacrificial layer.

In Step 820 a patterned second masking layer and a patterned photoresist layer are formed. A pattern on a mask (e.g., a photomask or reticle) is transferred to the photoresist layer, and then the photoresist layer is etched to form a patterned photoresist layer. Then the patterned photoresist layer is used as a mask to etch the second masking layer so as to form a patterned second masking layer.

In Step 830 the first taper trenches are formed. The patterned photoresist layer and patterned second masking layer are used as a hard mask. Etching the sacrificial layer is performed to form the first taper trenches in the second masking layer and the sacrificial layer of the stack layer. And then, the patterned photoresist layer is removed so as to form a first patterned sacrificial layer.

In Step 840 the photoresist is spin coated, wherein comprises etching back the photoresist. The photoresist fills in the first taper trench and then etches back the photoresist.

In Step 850 the patterned second masking layer is stripped to expose the part of the first patterned sacrificial layer.

In Step 860 the second taper trenches are formed. The exposed first patterned sacrificial layer is etched to form the second taper trenches in the first patterned sacrificial layer.

In Step 870 the patterned first masking layer is formed. Stripping the photoresist filled in the first taper trench and using the second patterned sacrificial layer as a mask to etch the first masking layer so as to form the patterned first masking layer.

In the present embodiment, providing a method of duplicate the line density by double etching the sacrificial layer to produce a hard mask which line width is narrowed so as to get the smallest feature size.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming micro-patterns, comprising:
providing a substrate having a surface thereon, and forming a stack layer on the substrate;
etching a masking layer in the stack layer to form a patterned masking layer;
using the patterned masking layer as a hard mask and etching a sacrificial layer to form a plurality of first taper trenches in the sacrificial layer and a first patterned sacrificial layer;
filling a photoresist in the first taper trenches;
using the photoresist as a mask and forming a plurality of second taper trenches in the first patterned sacrificial layer; and
stripping the photoresist and forming a second patterned sacrificial layer by etching.

2. The method for forming micro-patterns of claim 1, wherein the step of filling a photoresist in the first taper trenches comprises:
stripping the patterned masking layer to expose the top of the first patterned sacrificial layer.

3. The method for forming micro-patterns of claim 1, wherein the method of forming the stack layer comprises:
forming the first masking layer on the substrate;
forming the sacrificial layer on the first masking layer; and
forming the second masking layer on the sacrificial layer.

4. The method for forming micro-patterns of claim 3, wherein the sacrificial layer and the first masking layer have an etch selectivity ratio and are respectively selected from two of polysilicon, silicon oxide, silicon nitride or nitride; and the sacrificial layer and the second masking layer have an etch selectivity ratio and are respectively selected from two of polysilicon, silicon oxide, silicon nitride or nitride.

5. The method for forming micro-patterns of claim 4, wherein the step of filling a photoresist in the first taper trenches comprises:
etching back the photoresist which is filled in the first taper trenches.

6. A method for forming micro-patterns, comprising:
forming a first masking layer on a substrate;
forming a sacrificial layer on the first masking layer;
forming a plurality of first taper trenches in the sacrificial layer;
filling a photoresist layer in the first taper trenches;
using the photoresist layer as a mask to form a plurality of second taper trenches in the sacrificial layer; and
stripping the photoresist layer and etching the first masking layer via the first taper trenches and the second taper trenches to form a patterned first masking layer.

7. The method for forming micro-patterns of claim 6, wherein the step of forming a plurality of first taper trenches in the sacrificial layer comprises:
forming a patterned second masking layer on the sacrificial layer; and
patterning the sacrificial layer to form the first taper trenches with the patterned second masking layer.

8. The method for forming micro-patterns of claim 7, wherein the sacrificial layer is a silicon dioxide layer, the first masking layer and the patterned second masking layer is a nitride layer.

9. The method for forming micro-patterns of claim 6, wherein the step of filling a photoresist layer in the first taper trenches comprises:
etching back the photoresist which is filled in the plurality of first taper trenches.

10. A method for forming micro-patterns, comprising:
forming a plurality of first taper trenches in a sacrificial layer;
filling a photoresist layer in the plurality of first taper trenches;
using the photoresist layer as a mask and forming a plurality of second taper trenches in the sacrificial layer; and
stripping the photoresist layer to be capable of patterning a layer by the first taper trenches and the second taper trenches in the sacrificial layer.

11. The method for forming micro-patterns of claim 10, wherein the step of forming a plurality of first taper trenches in a sacrificial layer comprises:
forming a patterned masking layer on the sacrificial layer; and
using the patterned masking layer to pattern the sacrificial layer to form the first taper trenches.

12. The method for forming micro-patterns of claim 11, wherein the sacrificial layer and the patterned masking layer have an etch selectivity ratio and are respectively selected from two of polysilicon, silicon oxide, silicon nitride or nitride.

13. The method for forming micro-patterns of claim 10, wherein the step of filling a photoresist layer in the plurality of first taper trenches comprises:
etching back the photoresist layer which fills in the first taper trenches.
